(19) United States
(12) Patent Application Publication
(10) Pub. No.: US 2023/0015073 A1
(43) Pub. Date: Jan. 19, 2023

(54) SEMICONDUCTOR STRUCTURE AND MEMORY

(71) Applicant: CHANGXIN MEMORY TECHNOLOGIES, INC., Hefei City (CN)

(72) Inventors: Minghao LI, hEFEI (CN); Fengqin Zhang, Hefei (CN); Weibing Shang, Hefei (CN)

(21) Appl. No.: 17/955,622

(22) Filed: Sep. 29, 2022

Related U.S. Application Data
(63) Continuation of application No. PCT/CN2022/098102, filed on Jun. 10, 2022.

(30) Foreign Application Priority Data
Apr. 7, 2022 (CN) 202210359900.X

(51) Int. Cl. H01L 27/108; G11C 11/4096

(52) U.S. Cl. CPC H01L 27/10897; G11C 11/4096

(57) ABSTRACT

A semiconductor structure and a memory are provided. The semiconductor structure includes an active region pattern, a first type of grid patterns overlapping with the active region pattern and extending along the first direction, and a metal layer pattern extending along the first direction. The metal layer pattern is in contact with an active region pattern arranged on both sides of the first type of grid patterns through a contact hole pattern.

### CROSS-REFERENCE TO RELATED APPLICATIONS

This is a continuation of International Patent Application No. PCT/CN2022/098102, filed on Jun. 10, 2022, which claims priority to Chinese Patent Application No. 202210359900.X, filed on Apr. 7, 2022 and entitled “SEMICONDUCTOR STRUCTURE LAYOUT AND SEMICONDUCTOR STRUCTURES”. The disclosures of International Patent Application No. PCT/CN2022/098102 and Chinese Patent Application No. 202210359900.X are hereby incorporated by reference in their entireties.

### BACKGROUND

With the increasing scale of the design field of micro processing, memory area occupies most of the chip area, and with the development of technology, the proportion of memory in the chip gets larger. Therefore, designing high-density memory can reduce the chip area to a certain extent, thereby reducing the cost. With the increase of the density of the memory, the existing semiconductor structure layout has the problem of low reliability, which cannot meet the demand.

### SUMMARY

The present disclosure relates to the field of integrated circuits, and more particularly to a semiconductor structure and a memory.

In a first aspect, the present disclosure provides a semiconductor structure, which includes: an active region pattern; a first type of grid patterns which are overlapped with the active region pattern and extend along a first direction; and a metal layer pattern which extends along the first direction, and is in contact with the active region pattern arranged on both sides of the first type of grid patterns through a contact hole pattern.

In a second aspect, the present disclosure also provides a memory comprising the semiconductor structure described above.

### BRIEF DESCRIPTION OF THE DRAWINGS

FIG. 1A is a schematic structural diagram of a dynamic random access memory.

FIG. 1B is an enlarged partial view of the portion indicated by a dotted box A in FIG. 1A.

FIG. 1C is a schematic diagram of a read-write conversion circuit unit.

FIG. 2 is a semiconductor structure according to a first embodiment of the present disclosure.

FIG. 3 is a circuit diagram of a semiconductor structure formed according to the first embodiment of the present disclosure.

FIG. 4 is a semiconductor structure according to a second embodiment of the present disclosure.

FIG. 5 is a circuit diagram of a semiconductor structure formed according to the second embodiment of the present disclosure.

FIG. 6 is a semiconductor structure according to a third embodiment of the present disclosure.

FIG. 7 is a circuit diagram of a semiconductor structure formed according to the third embodiment of the present disclosure.

### DETAILED DESCRIPTION

The embodiments of the semiconductor structure and the memory comprising the semiconductor structure provided in the present disclosure are described in detail below with reference to the accompanying drawings.

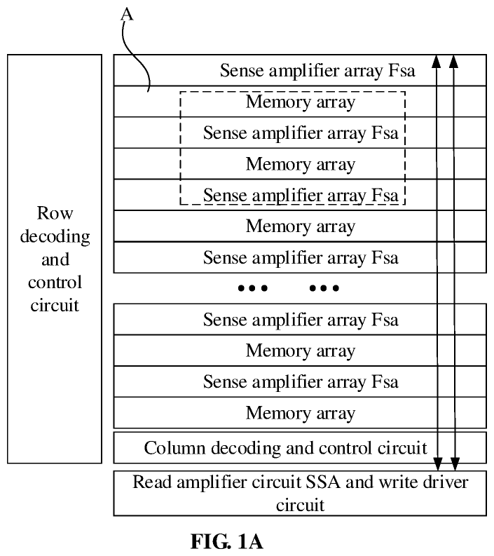

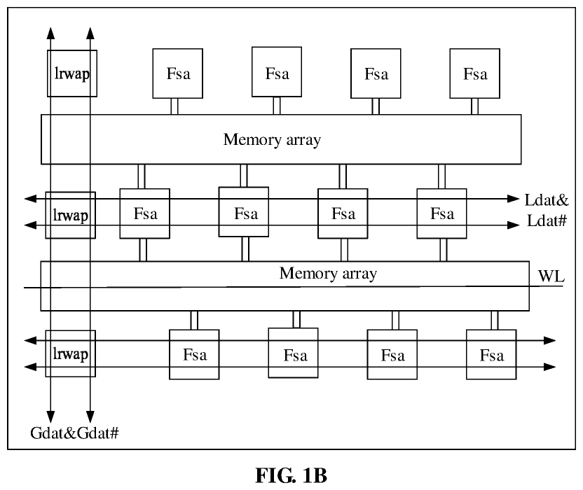

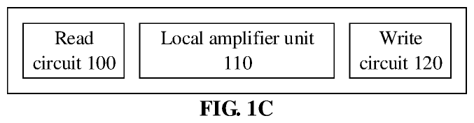

Referring to FIG. 1A which is a schematic structural diagram of a dynamic random access memory, the dynamic random access memory includes a memory array, a sense amplifier array Fsa, a row decoding and control circuit XDEC, a column decoding and control circuit YDEC, and a read amplifier circuit SSA and a write driver circuit for a Gdat&Gdat# signal.

FIG. 1B is a partial enlarged view of the portion indicated by the dotted line box A in FIG. 1A. When a word line (WL) is selected (controlled by XDEC decoding), data is transmitted to the sense amplifier arrays on the upper and lower sides, and amplified by the sense amplifier arrays, and then written back to memory cells of the memory array connected to the selected word line. When the data needs to be changed or rewritten, the column decoding YDEC selects a position of the corresponding sense amplifier array, and data is transmitted from a group of data lines Gdat&Gdat# to a group of data lines Ldat&Ldat# through a local read-write conversion circuit (lrwap), and then written into the corresponding sense amplifier array and the memory cells of the connected memory array. When data is read out, a transmission direction of data is opposite. The column decoding YDEC selects the position of the corresponding sensitive amplifier array, and the data is transmitted to a group of data lines Ldat&Ldat#, then transmitted to a group of data lines Gdat&Gdat# by the local read-write conversion circuit (lrwap), and amplified and outputted by read amplifier circuit SSA.

The Gdat&Gdat# signals are respectively transmitted on the data lines Gdat&Gdat#, and the Ldat&Ldat# signals are respectively transmitted on the data lines Ldat&Ldat#.

The read-write conversion circuit (lrwap) includes a plurality of read-write conversion circuit units. FIG. 1C is a schematic diagram of the read-write conversion circuit units, each read-write conversion circuit unit includes a read circuit 100, a local amplifier unit 110 and a write circuit 120.

The embodiment of the present disclosure provides a semiconductor structure for realizing the functions of a read-write conversion circuit, and the semiconductor structure obtained has high reliability. The semiconductor structure provided by the embodiment of the present disclosure includes an active region pattern, a first type of grid patterns and a metal layer pattern. The first type of grid patterns is overlapped with the active region pattern and extends along a first direction. The metal layer pattern also extends along the first direction, and the metal layer pattern is in contact with an active region pattern arranged on both sides of the first type of grid patterns through a contact hole pattern. The metal layer pattern provided by the embodiment is closest to the active region pattern in the semiconductor structure. In the semiconductor structure provided by the embodiment of the present disclosure, the extension direction of the first type of grid patterns is consistent with the extension direction of the metal layer pattern. Compared with the structure in which the extension direction of the first type of grid patterns is perpendicular to the extension direction of the metal layer pattern, the length of the first type of grid patterns increases in a case that the structure and the semiconductor structure provided by the embodiment of the present disclosure have the same area, thereby increasing the length of the contact hole pattern connecting the metal layer pattern with the corresponding active region pattern, improving the reliability of the semiconductor structure formed, and optimizing the performance of the device .

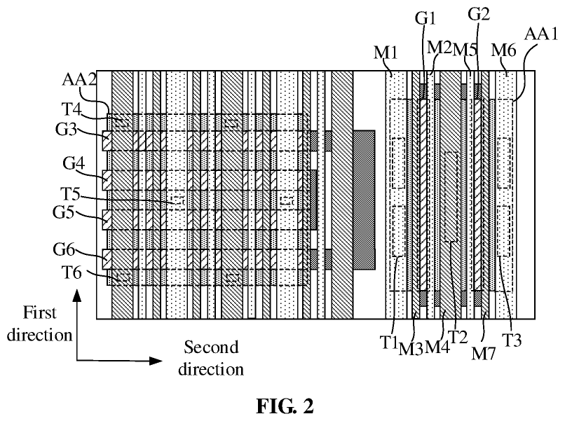

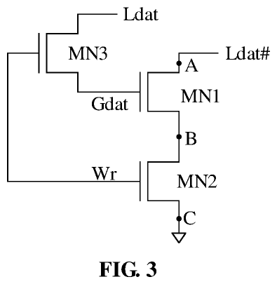

FIG. 2 is a semiconductor structure provided by a first embodiment of the present disclosure, and FIG. 3 is a circuit diagram of a semiconductor structure formed by the first embodiment of the present disclosure. The circuit is an example of a write conversion circuit for the Ldat&Ldat# signal. In order to show the structure of the semiconductor structure of the present disclosure clearly, the first type of grid patterns, the second type of grid pattern, the active region pattern and the contact hole pattern blocked by the metal layer pattern are drawn by dotted lines.

Referring to FIG. 3, the circuit includes a first N-Channel Metal-Oxide semiconductor (NMOS) transistor MN1, a second NMOS transistor MN2, and a third NMOS transistor MN3. A first end of the first NMOS transistor MN1 is connected to the data line Ldat#, a second end of the first NMOS transistor MN1 is connected to a first end of the second NMOS transistor MN2, and a control end of the first NMOS transistor MN1 is controlled by the Gdat signal. A second end of the second NMOS transistor MN2 is grounded and a control end of the second NMOS transistor MN2 is controlled by a write drive signal Wr. A first end of the third NMOS transistor MN3 is connected to the data line Ldat, a second end of the third NMOS transistor MN3 is connected to a control end of the first NMOS transistor MN1 to provide the Gdat signal, and the control end of the third NMOS transistor MN3 is controlled by a write drive signal Wr.

In the first embodiment, the semiconductor structure constitutes a first NMOS transistor MN1 pattern, a second NMOS transistor MN2 pattern, and a third NMOS transistor MN3 pattern.

Referring to FIG. 2, the active region pattern includes a first active region pattern AA1, the first type of grid patterns includes a first grid pattern G1, and the metal layer pattern includes a first type of metal line patterns and a second type of metal line patterns.

The first grid pattern G1 extends along a first direction and is overlapped with the first active region pattern AA1. In the embodiment, the first type of grid patterns further includes a second grid pattern G2 spaced from the first grid pattern G1 in a second direction, the second grid pattern G2 is overlapped with the first active region pattern AA1 and in parallel with the first grid pattern G1. The second grid pattern G2 extends in the first direction. In the embodiment, the first direction is perpendicular to the second direction.

In some embodiments, the first direction may be a direction parallel to a bit line of the semiconductor structure, and the second direction may be a direction perpendicular to the bit line of the semiconductor structure, that is, the second direction may be a direction parallel to a word line of the semiconductor structure.

In the embodiment, the first grid pattern G1, the second grid pattern G2, and the first active region pattern AA1 constitute the third NMOS transistor MN3 pattern. In other embodiments of the present disclosure, the first type of grid patterns includes only the first grid pattern G1, and the first grid pattern G1 and the first active region pattern AA1 constitute the third NMOS transistor MN3 pattern.

The metal layer pattern includes a first type of metal line patterns and a second type of metal line patterns. The first type of metal line patterns and the second type of metal line patterns may be formed in different operations. For example, the first type of metal line patterns is formed first, and then the second type of metal line patterns is formed. Although the first type of metal line patterns and the second type of metal line patterns are formed in different operations, the first type of metal line patterns and the second type of metal line patterns both are in the same metal layer pattern.

The first type of metal line patterns includes a first metal line pattern M1 and a second metal line pattern M2 which are spaced in the second direction and extend along the first direction. The first metal line pattern M1 is in contact with a first active region pattern AA1 arranged on a first side of the first grid pattern G1 through a first contact hole pattern T1. A gap distance between the first metal line pattern M1 and the first grid pattern G1 is set, which at least ensure there is no overlapping area of an orthographic projection between the first metal line pattern M1 and the first grid pattern G1, to avoid the performance of the semiconductor structure from being affected due to contact of the first contact hole pattern T1 with the first grid pattern G1 when the first active region pattern AA1 and the first metal line pattern M1 are connected through the first contact hole pattern. The set distance can be set according to actual process requirements and circuit requirements. The process requirements include a maximum distance that can actually be achieved, and the circuit requirements include a parasitic capacitance between the first contact hole pattern T1 and the first grid pattern G1, and at least partial overlapping of the orthographic projection between the second metal line pattern M2 and the first grid pattern G1, that is, the second metal line pattern M2 and the first grid pattern G1 have at least a partially overlapping area on the orthographic projection. Since there is no need for the second metal line pattern M2 through the contact hole pattern to be in contact with the first active region pattern AA1, the second metal line pattern M2 and the first grid pattern G1 may overlap without affecting the performance of the semiconductor structure.

In the second direction, the width of the second metal line pattern M2 is smaller than the width of the first metal line pattern M1. That is, the width of the first metal line pattern M1 is larger than the width of the second metal line pattern M2, which provide a sufficient width for the first metal line pattern M1 if the area unchanged, for making the first metal wire pattern M1 be in contact with the first active area pattern AA1 arranged on the first side of the first grid pattern G1 through the first contact hole pattern T1.

The second type of metal line patterns includes a third metal line pattern M3 and a fourth metal line pattern M4 which are spaced in the second direction and extend along the first direction. The third metal line pattern M3 is arranged between the first metal line pattern M1 and the second metal line pattern M2. The fourth metal line pattern M4 is arranged on a side of the second metal line pattern M2 away from the first metal line pattern M1, and the fourth metal line pattern M4 is in contact with the first active region pattern AA1 arranged on a second side of the first grid pattern G1 through the second contact hole pattern T2. The second side is opposite to the first side.

A gap distance between the fourth metal line pattern M4 and the first grid pattern G1 is set, that is, there is no overlapping area between the fourth metal line pattern M4 and the first grid pattern G1, to avoid the performance of the semiconductor structure from being affected due to contact of the second contact hole pattern T2 with the first grid pattern G1 when the first active region pattern AA1 and the fourth metal line pattern M4 are connected through the second contact pattern T2. The set distance can be set according to actual process requirements and circuit requirements. The process requirements include a maximum distance that can actually be achieved, and the circuit requirements include a parasitic capacitance between the first contact hole pattern T1 and the first grid pattern G1, and at least partial overlapping between the third metal line pattern M3 and the first grid pattern G1, that is, the third metal line pattern M3 and the first grid pattern G1 have at least a partially overlapping area. Since there is no need for the third metal line pattern M3 through the contact hole pattern to be in contact with the first active region pattern AA1, the third metal line pattern M3 and the first grid pattern G1 may overlap without affecting the performance of the semiconductor structure.

In the second direction, the width of the third metal line pattern M3 is smaller than the width of the fourth metal line pattern M4. That is, the width of the fourth metal line pattern M4 is larger than the width of the third metal line pattern M3, which provide a sufficient width for the fourth metal line pattern M4 if the area unchanged, for making the fourth metal line pattern M4 be in contact with the first active region pattern AA1 arranged on the second side of the first grid pattern G1 through the second contact hole pattern T2.

With the increase of the integration of semiconductor structure, the process size is gradually reduced, and the contact holes are getting smaller. The performance of semiconductor structure decreases due to the defect of contact hole, which affects the performance and yield rate of the semiconductor structure. In the semiconductor structure provided by the embodiment, the first grid pattern G1 extends in a first direction. The first metal line pattern M1 and the fourth metal line pattern M4 also extend in the first direction, that is, the extension direction of the first grid pattern G1 is the same as that of the first metal line pattern M1 and the fourth metal line pattern M4. Compared with the structure in which the extension direction of the first grid pattern G1 is perpendicular to the extension direction of the first metal line pattern M1 and the fourth metal line pattern M4, when the width (short side) of the first grid pattern G1 in the second direction is less than or equal to the distance between the first metal line pattern M1 and the fourth metal line pattern M4, that is, when the orthographic projection of the first grid pattern G1 does not overlap the orthographic projection the first metal line pattern M1 and the fourth metal line pattern M4, the first grid pattern G1 does not affect the overlapping between the metal line pattern and the active region pattern as the width of the first grid pattern G1 increases in the second direction. Therefore, the length of the first contact hole pattern T1 connecting the first metal line pattern M1 with the first active region pattern AA1 and the length of the second contact hole pattern T2 connecting the fourth metal line pattern M4 with the first active region pattern AA1 can be increased under a condition that the size of the first grid pattern G1 meets the requirements, thereby improving the reliability of the formed semiconductor structure, and optimizing the performance of the device. For example, in the embodiment, the fourth metal line pattern M4 is connected to the first active region pattern AA1 through a second contact hole pattern T2, the connectable area of the second contact hole pattern T2 is greatly extended, thereby improving the reliability of the formed semiconductor structure, and optimizing the performance of the device.

In some embodiments, with the extension of the length of the first grid pattern G1, since the length of the first contact hole pattern T1 has a maximum limit, at least two first contact hole patterns T1 connected in parallel may be provided, and the first contact hole pattern T1 is arranged in the first direction. Specifically, the first metal line pattern M1 is in contact with the first active region pattern AA1 arranged on the first side of the first grid pattern G1 through at least two first contact hole patterns T1 arranged in parallel. For example, in the embodiment, the first metal line pattern M1 is in contact with the first active region pattern AA1 on the first side of the first grid pattern G1 through two first contact hole patterns T1 arranged in parallel. When a defect occurs in one of the first contact hole patterns T1, the remaining first contact hole patterns T1 may continue to be used. The number of the first contact hole patterns T1 is increased, thereby improving the reliability of the connection between the first metal line pattern M1 and the first active region pattern AA1, and greatly improving the reliability of the semiconductor structure.

In the embodiment, in the second direction, the width of the first grid pattern G1 is smaller than the distance between the first metal line pattern M1 and the fourth metal line pattern M4, to avoid the contact between the first contact hole pattern T1 and the second contact hole pattern T2 with the first grid pattern G1 and improve the reliability of the semiconductor structure.

In the present embodiment, the first type of metal line patterns further includes a fifth metal line pattern M5 and a sixth metal line pattern M6 which are spaced in the second direction and extend in the first direction. The sixth metal line pattern M6 is connected to the first active region pattern AA1 on the side of the second grid pattern G2 away from the first grid pattern G1 through the third contact hole pattern T3. The fifth metal line pattern M5 and the second grid pattern G2 overlap at least partially on the orthographic projection, that is, there is at least partially overlapping area of the orthographic projection between the fifth metal line pattern M5 and the second grid pattern G2. Since the fifth metal line pattern M5 does not need to be in contact with the first active region pattern AA1 through the contact hole pattern, the fifth metal line pattern M5 and the second grid pattern G2 may overlap, thereby no affecting the performance of the semiconductor structure. A gap distance between the sixth metal line pattern M6 and the second grid pattern G2 is set, that is, at least there is no overlapping area of the orthographic projection between the sixth metal line pattern M6 and the second grid pattern G2, so as to avoid the performance of the semiconductor structure from being affected due to contact of avoid the third contact hole pattern T3 with the second grid pattern G2 when the first active region pattern AA1 and the sixth metal line pattern M6 are connected through the third contact hole pattern T3. The set distance can be set according to actual process requirements and circuit requirements. The process requirements include a maximum distance that can actually be achieved, and the circuit requirements include the parasitic capacitance between the third contact hole pattern T3 and the first grid pattern G1.

In the second direction, the width of the fifth metal line pattern M5 is smaller than the width of the sixth metal line pattern M6. That is, the width of the sixth metal line pattern M6 is larger than the width of the fifth metal line pattern M5, which provide a sufficient width for the sixth metal line pattern M6 if the area unchanged, for making the sixth metal line pattern M6 be in contact with the first active region pattern AA1 arranged on the first side of the second grid pattern G2 through the third contact hole pattern T3.

In the present embodiment, the second type of metal line patterns further includes a seventh metal line pattern M7 arranged between the fifth metal line pattern M5 and the sixth metal line pattern M6 and extending in the first direction. The fifth metal line pattern M5, the seventh metal line pattern M7, and the sixth metal line pattern M6 are spaced in the second direction. The seventh metal line pattern M7 and the second grid pattern G2 overlap at least partially on the orthographic projection, that is, there is at least a partially overlapping area on the orthographic projection between the seventh metal line pattern M7 and the second grid pattern G2. Since the seventh metal line pattern M7 does not need to be in contact with the first active region pattern AA1 through the contact hole pattern, the seventh metal line pattern M7 may overlap with the second grid pattern G2 on the orthographic projection without affecting the performance of the semiconductor structure.

In the second direction, the width of the second grid pattern G2 is smaller than the distance between the fourth metal line pattern M4 and the sixth metal line pattern M6, so as to avoid the contact of the second contact hole pattern T2 and the third contact hole pattern T3 with the second grid pattern G2, thereby improving the reliability of the semiconductor structure.

The semiconductor structure further includes a second type of grid patterns overlapping the active region pattern and extending in the second direction, and the metal layer pattern is in contact with an active region pattern arranged on both sides of the second type of grid patterns through a contact hole pattern. In some embodiments, the width (i.e., the grid length of the second type of grid patterns) of the second type of grid patterns in the first direction is less than the width (i.e., the grid length of the first type of grid patterns) of the first type of grid patterns in the second direction. In the semiconductor structure provided by the embodiment of the present disclosure, the grid pattern having longer grid length (for example, the first grid pattern G1 and the second grid pattern G2) are arranged in parallel (i.e. in the same direction) with the metal layer pattern. With the increase of the grid length of the first type of grid pattern, the grid pattern does not affect the overlapping between the metal line pattern and the active region pattern, thereby improving the reliability of semiconductor structure by increasing the size or number of contact hole patterns. A grid pattern having a shorter grid length (e.g. a third grid pattern G3, a fourth grid pattern G4, a fifth grid pattern G5, and a sixth grid pattern G6) is arranged perpendicular to the metal layer pattern. Due to the short grid length of the second type of grid patterns, the exposed area of the active area pattern is large, the contact area between the metal line pattern and the active region pattern is large, the contact hole pattern can be arranged to be large, thereby improving the reliability of semiconductor structure. In addition, if the second type of grid patterns is arranged in parallel (i.e. in the same direction) with the metal layer pattern, the number of contact hole patterns is not changed under the limit of the number of metal line patterns of the metal layer pattern, thereby reducing the performance of the second type of grid pattern. Therefore, in the embodiment, the second type of grid patterns are arranged to be perpendicular with the metal layer pattern, and a plurality of second type of grid patterns in parallel can be arranged, thereby improving the overall performance of the semiconductor structure, and improving a distribution density of the grid patterns, and increasing the integration level of the semiconductor structure. In semiconductor structures, the grid length of low-voltage devices is usually long, while the grid length of high-voltage devices is short.

In particular, referring to FIG. 2, in the present embodiment, the active region pattern includes a second active region pattern AA2, and the second type of grid pattern includes a third grid pattern G3, a fourth grid pattern G4, a fifth grid pattern G5 and a sixth grid pattern G6.

In the second direction, the second active region pattern AA2 and the first active region pattern AA1 are spaced or arranged in parallel.

The third grid pattern G3, the fourth grid pattern G4, the fifth grid pattern G5, and the sixth grid pattern G6 are spaced in the first direction and all extend along the second direction and overlap the second active region pattern AA2. The third grid pattern G3 and the sixth grid pattern G6 are arranged in parallel. For example, the third grid pattern G3 and the sixth grid pattern G6 are connected in parallel through a connection pattern (not shown in FIG. 2). The third grid pattern G3, the sixth grid pattern G6 and the first active region pattern AA1 constitute the first NMOS transistor MN1 pattern. The fourth grid pattern G4 and the fifth grid pattern G5 are arranged in parallel. For example, the fourth grid pattern G4 and the fifth grid pattern G5 are connected in parallel through a connection pattern (not shown in FIG. 2), and the fourth grid pattern G4, the fifth grid pattern G5 and the first active region pattern AA1 constitute the second NMOS transistor MN2 pattern.

At least two fourth contact hole patterns T4 arranged in parallel are arranged on the side of the third grid pattern G3 away from the fourth grid pattern G4, and each fourth contact hole pattern T4 is overlapped with the second active region pattern AA2. When a defect occurs in one of the fourth contact hole patterns T4, the remaining fourth contact hole patterns T4 may continue to be used, which greatly improves the reliability of the semiconductor structure. As an example, in the embodiment, the semiconductor structure includes two fourth contact hole patterns T4 arranged in parallel according to the lengths of the third grid pattern G3 and the first active region pattern AA1.

At least two fifth contact hole patterns T5 arranged in parallel are arranged between the fourth grid pattern G4 and the fifth grid pattern G5, and each fifth contact hole pattern T5 is overlapped with the second active region pattern AA2. When a defect occurs in one of the fifth contact hole patterns T5, the remaining fifth contact hole patterns T5 may continue to be used, which greatly improves the reliability of the semiconductor structure. As an example, in the embodiment, the semiconductor structure includes two fifth contact hole patterns T5 arranged in parallel according to the lengths of the fourth grid pattern G4 and the first active region pattern AA1.

At least two sixth contact hole patterns T6 arranged in parallel are arranged on the side of the sixth grid pattern G6 away from the fifth grid pattern G5, and each sixth contact hole pattern T6 is overlapped with the second active region pattern AA2. When a defect occurs in one of the sixth contact hole patterns T6, the remaining sixth contact hole patterns T6 can continue to be used, which greatly improves the reliability of the semiconductor structure. As an example, in the embodiment, the semiconductor structure includes two sixth contact hole patterns T6 arranged in parallel according to the lengths of the sixth grid pattern G6 and the first active region pattern AA1.

The metal layer pattern is in contact with the second active region pattern AA2 through the fourth contact hole pattern T4, the fifth contact hole pattern T5 and the sixth contact hole pattern T6. As an example, in the present embodiment, the metal layer pattern includes a first type of metal line patterns and a second type of metal line patterns. The first type of metal line patterns is connected to the first active region pattern AA1 through a fourth contact hole pattern T4 and a sixth contact hole pattern T6, and the second type of metal line patterns are connected to the first active region pattern AA1 through a fifth contact hole pattern T5.

The semiconductor structure provided by the first embodiment of the present disclosure can realize the write conversion circuit for the Ldat/Ldat# signal shown in FIG. 3.

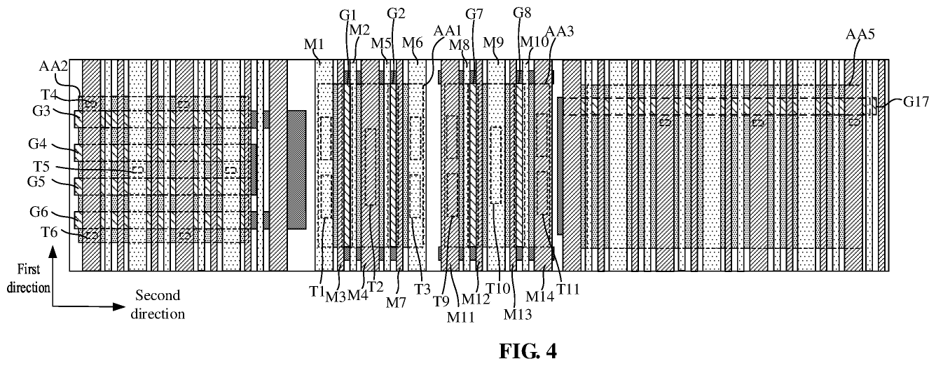

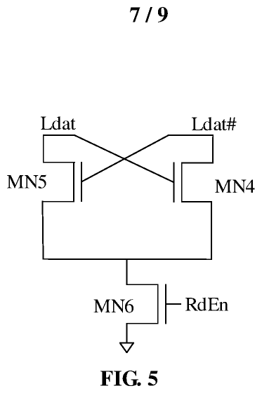

On the basis of the semiconductor structure shown in the first embodiment, the second embodiment of the disclosure also provides a semiconductor structure. FIG. 4 is a semiconductor structure provided by the second embodiment of the disclosure, and FIG. 5 is a circuit diagram of a semiconductor structure formed by the second embodiment of the disclosure. The circuit is a partial circuit example of a local amplifier for the Ldat/Ldat# signal.

Referring to FIG. 5, in the second embodiment, the circuit includes a fourth NMOS transistor MN4, a fifth NMOS transistor MN5, and a sixth NMOS transistor NM6. A first end of the fourth NMOS transistor MN4 is connected to the data line Ldat#, a second end of the fourth NMOS transistor MN4 is connected to the first end of the sixth NMOS transistor NM6, and a control end of the fourth NMOS transistor MN4 is controlled by the Ldat signal. A first end of the fifth NMOS transistor MN5 is connected to the data line Ldat, a second end of the fifth NMOS transistor MN5 is connected to the first end of the sixth NMOS transistor NM6, and a control end of the fifth NMOS transistor MN5 is controlled by the Ldat# signal. A second end of the sixth NMOS transistor NM6 is grounded, and a control end of the sixth NMOS transistor NM6 is controlled by a read enable signal RdEn.

Referring to FIG. 4, in the second embodiment, the active region pattern further includes a third active region pattern AA3. The third active region pattern AA3 and the first active region pattern AA1 are spaced or arranged in parallel. Specifically, in the embodiment, the third active region pattern AA3 and the second active region pattern AA2 are arranged on opposite sides of the first active region pattern AA1 respectively.

The first type of grid patterns includes a seventh grid pattern G7 and an eighth grid pattern G8. The seventh grid pattern G7 and the eighth grid pattern G8 are spaced in the second direction and both extend along the first direction and overlap with the third active region pattern AA3. In the present embodiment, the seventh grid pattern G7 is close to the second grid pattern G2, and the eighth grid pattern G8 is far away from the second grid pattern G2. The seventh grid pattern G7 and the third active region pattern AA3 constitute the fourth NMOS transistor MN4 pattern, and the eighth grid pattern G8 and the third active region pattern AA3 constitute the fifth NMOS transistor MN5 pattern.

The metal layer includes a first type of metal line patterns and a second type of metal line pattern. The first type of metal line patterns includes an eighth metal line pattern M8, a ninth metal line pattern M9, and a tenth metal line pattern M10 spaced in the second direction. The ninth metal line pattern M9 is in contact with a third active region pattern AA3 arranged between the seventh grid pattern G7 and the eighth grid pattern G8 through a tenth contact hole pattern T10. The second type of metal line patterns includes an eleventh metal line pattern M11, a twelfth metal line pattern M12, a thirteenth metal line pattern M13 and a fourteenth metal line pattern M14 spaced in a second direction. The eighth metal line pattern M8 is arranged between the eleventh metal line pattern M11 and the twelfth metal line pattern M12. The ninth metal line pattern M9 is arranged between the twelfth metal line pattern M12 and the thirteenth metal line pattern M13. The tenth metal line pattern M10 is arranged between the thirteenth metal line pattern M13 and the fourteenth metal line pattern M14. The eleventh metal line pattern M11 is in contact with the third active region pattern AA3 on the side of the seventh grid pattern G7 away from the eighth grid pattern G8 through the ninth contact hole pattern T9, and the fourteenth metal line pattern M14 is in contact with the third active region pattern AA3 on the side of the eighth grid pattern G8 away from the seventh grid pattern G7 through the eleventh contact hole pattern T11.

In the second embodiment, the seventh grid pattern G7 and the eighth grid pattern G8 extend in the first direction. The eighth metal line pattern M8, the ninth metal line pattern M9, the tenth metal line pattern M10, the eleventh metal line pattern M11, the twelfth metal line pattern M12, the thirteenth metal line pattern M13 and the fourteenth metal line pattern M14 also extend in the first direction. That is, the seventh grid pattern G7 and the eighth grid pattern G8 extend in the same direction as the eighth metal line pattern M8, the ninth metal line pattern M9, the tenth metal line pattern M10, the eleventh metal line pattern M11, the twelfth metal line pattern M12, the thirteenth metal line pattern M13 and the fourteenth metal line pattern M14. Compared with the structure in which the extension direction of the seventh grid pattern G7 and the eighth grid pattern G8 are perpendicular to the extension directions of the eighth metal line pattern M8, the ninth metal line pattern M9, the tenth metal line pattern M10, the eleventh metal line pattern M11, the twelfth metal line pattern M12, the thirteenth metal line pattern M13 and the fourteenth metal line pattern M14, when the width (short side) of the seventh grid pattern G7 in the second direction is less than or equal to a distance between the ninth metal line pattern M9 and the eleventh metal line pattern M11, that is, when the orthographic projection of the seventh grid pattern G7 does not overlap the ninth metal line pattern M9 and the eleventh metal line pattern M11, the seventh grid pattern G7 does not affect the overlapping between of the metal line pattern and the active region pattern as the width of the seventh grid pattern G7 increases in the second direction. Therefore, the length of the ninth contact hole pattern and the tenth contact hole pattern can be increased under the condition that the size of the grid pattern meets the requirements, thereby improving the reliability of the formed semiconductor structure, and optimizing the performance of the device. Similarly, when the width (short side) of the eighth grid pattern G8 in the second direction is less than or equal to a distance between the ninth metal line pattern M9 and the fourteenth metal line pattern M14, that is, when the orthographic projection of the eighth grid pattern G8 does not overlap the ninth metal line pattern M9 and the fourteenth metal line pattern M14, the eighth grid pattern G8 does not affect the overlapping between the metal line pattern and the active region pattern as the width of the eighth grid pattern G8 increases in the second direction. Therefore, the length of the ninth contact hole pattern and the eleventh contact hole pattern can be increased under the condition that the size of the grid patterns meets the requirements, thereby improving the reliability of the formed semiconductor structure, and optimizing the performance of the device.

Additionally, in some embodiments, with the extension of the lengths of the seventh grid pattern G7 and the eighth grid pattern G8, since the length of the contact hole pattern has a maximum limitation, at least two ninth contact hole patterns arranged in parallel in the first direction, at least two tenth contact hole patterns in parallel in the first direction and at least two eleventh contact hole patterns arranged in parallel in the first direction may be arranged, thereby greatly improving the reliability of the semiconductor structure.

In the embodiment, in the second direction, the width of the eighth metal line pattern M8 and the width of the tenth metal line pattern M10 are smaller than the width of the ninth metal line pattern M9. That is, the width of the ninth metal line pattern M9 is larger than the width of the eighth metal line pattern M8 and the width of the tenth metal line pattern M10, which provide a sufficient width for the ninth metal line pattern M9 if the area unchanged, for connecting the ninth metal line pattern M9 be in contact with the third active region pattern AA3 arranged between the seventh grid pattern G7 and the eighth grid pattern G8 through the tenth contact hole pattern. In the second direction, the widths of the eleventh and fourteenth metal line patterns M11 and M14 are larger than the widths of the twelfth and thirteenth metal line patterns M12 and M13, which provide a sufficient width for the eleventh metal line pattern M11 and the fourteenth metal line pattern M14 if the area unchanged, for making the eleventh metal line pattern M11 be in contact with the third active region pattern AA3 on the side of the seventh grid pattern G7 away from the eighth grid pattern G8 through the ninth contact hole pattern, and making the fourteenth metal line pattern M14 be in contact with the third active region pattern AA3 on the side of the eighth grid pattern G8 away from the seventh grid pattern G7 through the eleventh contact hole pattern.

In the embodiment, in the second direction, the width of the seventh grid pattern G7 is smaller than a distance between the ninth metal line pattern M9 and the eleventh metal line pattern M11, and the width of the eighth grid pattern G8 is smaller than a distance between the ninth metal line pattern M9 and the fourteenth metal line pattern M14, so as to avoid the ninth contact hole from being in contact with the seventh grid pattern G7, avoid the tenth contact hole pattern from being in contact with the seventh grid pattern G7 and the eighth grid pattern G8, and avoid the eleventh contact hole pattern from being in contact with the eighth grid pattern G8, thereby improving the reliability of the semiconductor structure.

In the embodiment, the active region pattern further includes a fifth active region pattern AA5. In the second direction, the fifth active region pattern AA5 and the third active region pattern AA3 are spaced or arranged in parallel. The second type of grid patterns includes a seventeenth grid pattern G17 extending in the second direction and overlapping with the fifth active region pattern AA5. The seventeenth grid pattern G17 and the fifth active region pattern AA5 constitute a sixth NMOS transistor NM6 pattern. The metal layer is in contact with the fifth active region pattern AA5 on the side of the seventeenth grid pattern G17 through the contact hole pattern. As an example, in the embodiment, the metal layer pattern includes a first type of metal line patterns and a second type of metal line pattern. The second type of metal line patterns is in contact with the fifth active region pattern AA5 arranged on the side of the seventeenth grid pattern G17 through the contact hole pattern.

In the second embodiment, the semiconductor structure can form the write conversion circuit for the Ldat/Ldat# signal shown in FIG. 3 and a partial circuit of the local amplifier for the Ldat/Ldat# signal shown in FIG. 5.

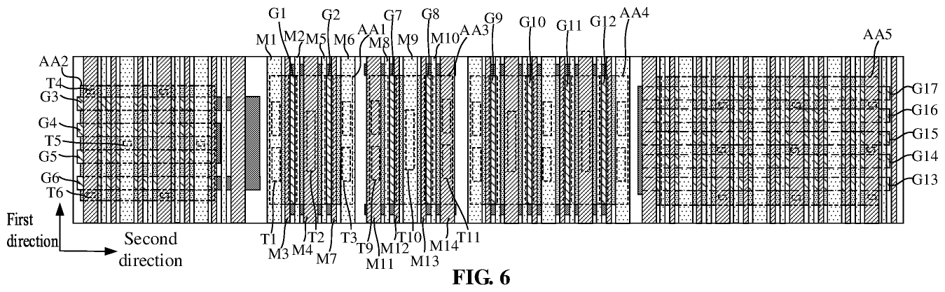

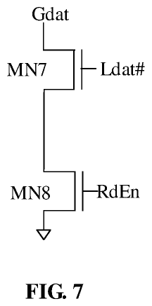

On that basis of the semiconductor structure shown in the second embodiment, a third embodiment of the present disclosure also provides a semiconductor structure. FIG. 6 is a semiconductor structure provided by the third embodiment of the present disclosure, and FIG. 7 is a circuit diagram of a semiconductor structure formed by the third embodiment of the disclosure. The circuit is an example of a conversion circuit to the Gdat/Gdat# signal when reading is performed by the Ldat/Ldat# signal.

Referring to FIG. 7, in the embodiment, the circuit includes a seventh NMOS transistor MN7 and an eighth NMOS transistor MN8. A first end of the seventh NMOS transistor MN7 is connected to the data line Gdat, a second end of the seventh NMOS transistor MN7 is connected to a first end of the eighth NMOS transistor MN8, a control terminal of the seventh NMOS transistor MN7 is controlled by the Ldat# signal, a second terminal of the eighth NMOS transistor MN8 is grounded, and a control terminal of the eighth NMOS transistor MN8 is controlled by a read enable signal RdEn.

In the third embodiment, referring to FIG. 6, the active region pattern further includes a fourth active region pattern AA4. The second active region pattern AA2, the first active region pattern AA1, the third active region pattern AA3, the fourth active region pattern AA4 and the fifth active region pattern AA5 are arranged sequentially in the second direction, and the fourth active region pattern AA4 is arranged between the third active region pattern AA3 and the fifth active region pattern AA5.

The first type of grid patterns includes a ninth grid pattern G9, a tenth grid pattern G10, an eleventh grid pattern G11 and a twelfth grid pattern G12 arranged in parallel. The ninth grid pattern G9, the tenth grid pattern G10, the eleventh grid pattern G11, and the twelfth grid pattern G12 are spaced in the second direction and all extend in the first direction, and overlap with the fourth active region pattern AA4. The metal layer is in contact with the fourth active region pattern AA4 on both sides of the ninth grid pattern G9, the tenth grid pattern G10, the eleventh grid pattern G11 and the twelfth grid pattern G12 through the contact hole pattern. In the present embodiment, the ninth grid pattern G9, the tenth grid pattern G10, the eleventh grid pattern G11 and the twelfth grid pattern G12 are sequentially arranged in a direction away from the eighth grid pattern G8.

The ninth grid pattern G9, the tenth grid pattern G10, the eleventh grid pattern G11, the twelfth grid pattern G12, and the fourth active region pattern AA4 constitute the seventh NMOS transistor pattern MN7.

In the third embodiment, the second type of grid pattern includes a thirteenth grid pattern G13, a fourteenth grid pattern G14, a fifteenth grid pattern G15 and a sixteenth grid pattern G16 arranged in parallel. The thirteenth grid pattern G13, the fourteenth grid pattern G14, the fifteenth grid pattern G15, and the sixteenth grid pattern G16 are spaced in the first direction and all extend along the second direction and overlap with the fifth active region pattern AAS. The metal layer is in contact with the fifth active region pattern AA5 on both sides of the thirteenth grid pattern G13, the fourteenth grid pattern G14, the fifteenth grid pattern G15 and the sixteenth grid pattern G16 through a contact hole pattern. The thirteenth grid pattern G13, the fourteenth grid pattern G14, the fifteenth grid pattern G15, and the sixteenth grid pattern G16 are connected in parallel through a connection pattern. The thirteenth grid pattern G13, the fourteenth grid pattern G14, the fifteenth grid pattern G15, the sixteenth grid pattern G16, and the fifth active region pattern AA5 constitute the eighth NMOS transistor MN8. In other embodiments of the present disclosure, only three second type of grid patterns may be provided, for example, only the thirteenth grid pattern G13, the fourteenth grid pattern G14, and the fifteenth grid pattern G15 are provided.

The semiconductor structure provided by the third embodiment of the present disclosure may form a write conversion circuit for the Ldat/Ldat# signal shown in FIG. 3, a partial circuit of a local amplifier for the Ldat/Ldat# signal shown in FIG. 5, and a conversion circuit to the Gdat/Gdat# signal when reading is performed by the Ldat/Ldat# signal shown in FIG. 7.

Another aspect of the embodiment of the application also provides a semiconductor structure. The semiconductor structure is manufactured according to the above embodiments, and an extension direction of a first type of grids is set to be consistent with an extension direction of the metal layer in the semiconductor structure. Compared with the structure in which the extension direction of the first type of grids is perpendicular to the extension direction of the metal layer, when the width (short side) of the first type of the grid in the second direction is less than or equal to a distance between adjacent thicker metal lines, that is, when the orthographic projection of the first type of grids does not overlap with adjacent thicker metal lines, the first type of grids does not affect the overlapping between the metal line and the active region as the width of the first type of the grids increases in the second direction. Therefore, the length of a contact hole connecting the metal layer and the corresponding active region can be increased under the condition that the size of the first type of grids meets the requirements, thereby improving the reliability of the semiconductor structure, and optimizing the performance of the device.

The foregoing is only preferred embodiments of the present disclosure, and it should be noted several improvements and modifications may be made by one of ordinary skill in the art without departing from the principles of the present disclosure, and such improvements and modifications are also to be considered to be within the scope of protection of the present disclosure.

1. A semiconductor structure comprises:
an active region pattern;
a first type of grid patterns overlapping with the active region pattern and extending along a first direction; and
a metal layer pattern extending along the first direction, wherein the metal layer pattern is in contact with the active region pattern arranged on both sides of the first type of grid patterns through a contact hole pattern.

2. The semiconductor structure of claim 1, wherein the active region pattern comprises a first active region pattern, the first type of grid patterns comprises a first grid pattern, and the metal layer pattern comprises:
a first type of metal line patterns comprising a first metal line pattern and a second metal line pattern which are spaced in a second direction, wherein the first metal line pattern is in contact with the first active region pattern arranged on a first side of the first grid pattern through a first contact hole pattern; and
a second type of metal line patterns comprising a third metal line pattern and a fourth metal line pattern which are spaced in the second direction, wherein the third metal line pattern is arranged between the first metal line pattern and the second metal line pattern, the fourth metal line pattern is arranged on a side of the second metal line pattern away from the first metal line pattern, the fourth metal line pattern is in contact with the first active region pattern arranged on a second side of the first grid pattern through a second contact hole pattern, the second side is opposite to the first side.

3. The semiconductor structure of claim 2, wherein in the second direction, a width of the second metal line pattern is smaller than a width of the first metal line pattern, and a width of the third metal line pattern is smaller than a width of the fourth metal line pattern.

4. The semiconductor structure of claim 2, wherein in the second direction, a width of the first grid pattern is smaller than a distance between the first metal line pattern and the fourth metal line pattern.

5. The semiconductor structure of claim 4, wherein the second metal line pattern and the third metal line pattern are at least partially overlapped with the first grid pattern.

6. The semiconductor structure of claim 2, wherein the first metal line pattern is in contact with the first active region pattern arranged on the first side of the first grid pattern through at least two first contact hole patterns arranged in parallel, and the fourth metal line pattern is in contact with the first active region pattern on the second side of the first grid pattern through at least two second contact hole patterns arranged in parallel.

7. The semiconductor structure of claim 2, wherein the first type of grid patterns further comprises a second grid pattern spaced from the first grid pattern in the second direction, the second grid pattern is overlapped with the first active region pattern and in parallel with the first grid pattern,
the first type of metal line patterns further comprises a fifth metal line pattern and a sixth metal line pattern which are spaced in the second direction, wherein the sixth metal line pattern is connected to the first active region pattern on a side of the second grid pattern away from the first grid pattern through a third contact hole pattern; and
the second type of metal line patterns further comprises a seventh metal line pattern arranged between the fifth metal line pattern and the sixth metal line pattern.

8. The semiconductor structure of claim 7, wherein in the second direction, a width of the second grid pattern is smaller than a distance between the fourth metal line pattern and the seventh metal line pattern.

9. The semiconductor structure of claim 7, wherein the fifth metal line pattern and the seventh metal line pattern are at least partially overlapped with the second grid pattern.

10. The semiconductor structure of claim 1, further comprising a second type of grid patterns, wherein the second type of grid patterns is overlapped with the active region pattern and extends along a second direction, and the metal layer pattern is in contact with the active region pattern arranged on both sides of the second type of grid patterns through the contact hole pattern.

11. The semiconductor structure of claim 10, wherein a width of the second type of grid patterns in the first direction is smaller than a width of the first type of grid patterns in the second direction.

12. The semiconductor structure of claim 11, wherein the active region pattern comprises a second active region pattern, the second type of grid patterns comprises a third grid pattern, a fourth grid pattern, a fifth grid pattern and a sixth grid pattern, wherein the third grid pattern, the fourth grid pattern, the fifth grid pattern and the sixth grid pattern are spaced in the first direction and all extend along the second direction, and are overlapped with the second active region pattern, the fourth grid pattern and the fifth grid pattern are arranged in parallel, and the third grid pattern and the sixth grid pattern are arranged in parallel;
at least two fourth contact hole patterns arranged in parallel are arranged on a side of the third grid pattern away from the fourth grid pattern and overlapped with the second active region pattern;
at least two fifth contact hole patterns arranged in parallel are arranged between the fourth grid pattern and the fifth grid pattern, and overlapped with the second active region pattern;
at least two sixth contact hole patterns arranged in parallel are arranged on a side of the sixth grid pattern away from the fifth grid pattern, and overlapped with the second active region pattern; and
the metal layer pattern is in contact with the second active region pattern through the fourth contact hole pattern, the fifth contact hole pattern and the sixth contact hole pattern.

13. The semiconductor structure of claim 1, wherein the active region pattern further comprises a third active region pattern;
the first type of grid patterns comprises a seventh grid pattern and an eighth grid pattern, the seventh grid pattern and the eighth grid pattern are spaced in a second direction and both extend along the first direction and are overlapped with the third active region pattern;
the metal layer pattern comprises:
a first type of metal line patterns comprising an eighth metal line pattern, a ninth metal line pattern and a tenth metal line pattern which are spaced in the second direction, wherein the ninth metal line pattern is in contact with the third active region pattern between the seventh grid pattern and the eighth grid pattern through a tenth contact hole pattern; and
a second type of metal line patterns comprising an eleventh metal line pattern, a twelfth metal line pattern, a thirteenth metal line pattern and a fourteenth metal line pattern which are spaced in the second direction, wherein the eighth metal line pattern is arranged between the eleventh metal line pattern and the twelfth metal line pattern, the ninth metal line pattern is arranged between the twelfth metal line pattern and the thirteenth metal line pattern, the tenth metal line pattern is arranged between the thirteenth metal line pattern and the fourteenth metal line pattern, the eleventh metal line pattern is in contact with the third active region pattern on a side of the seventh grid pattern away from the eighth grid pattern through a ninth contact hole pattern, the fourteenth metal line pattern is in contact with the third active region pattern on a side of the eighth grid pattern away from the seventh grid pattern through an eleventh contact hole pattern.

14. The semiconductor structure of claim 13, wherein in the second direction, a width of the seventh grid pattern is smaller than a distance between the ninth metal line pattern and the eleventh metal line pattern, and a width of the eighth grid pattern is smaller than a distance between the ninth metal line pattern and the fourteenth metal line pattern.

15. The semiconductor structure of claim 1, wherein the active region pattern comprises a fourth active region pattern, the first type of grid patterns comprises a ninth grid pattern, a tenth grid pattern, an eleventh grid pattern and a twelfth grid pattern arranged in parallel, the ninth grid pattern, the tenth grid pattern, the eleventh grid pattern and the twelfth grid pattern are spaced in a second direction and all extend along the first direction, and are overlapped with the fourth active region pattern, and the metal layer pattern is in contact with the fourth active region pattern on both sides of the ninth grid pattern, the tenth grid pattern, the eleventh grid pattern and the twelfth grid pattern through the contact hole pattern.

16. The semiconductor structure of claim 15, wherein the active region pattern comprises a fifth active region pattern, a second type of grid patterns comprises a thirteenth grid pattern, a fourteenth grid pattern, a fifteenth grid pattern and a sixteenth grid pattern arranged in parallel, the thirteenth grid pattern, the fourteenth grid pattern, the fifteenth grid pattern and the sixteenth grid pattern are spaced in the first direction and all extend along the second direction, and are overlapped with the fifth active region pattern, and the metal layer pattern is in contact with the fifth active region pattern on both sides of the thirteenth grid pattern, the fourteenth grid pattern, the fifteenth grid pattern and the sixteenth grid pattern through the contact hole pattern.

17. The semiconductor structure of claim 13, wherein the active region pattern further comprises a fifth active region pattern, a second type of grid patterns comprises a seventeenth grid pattern extending along the second direction and overlapping with the fifth active region pattern, and the metal layer pattern is in contact with the fifth active region pattern arranged on one side of the seventeenth grid pattern through the contact hole pattern.

18. A memory comprising the semiconductor structure of claim 1.
